(19) United States
(12) Patent Application Publication
(10) Pub. No.: US 2007/0272441 A1
(43) Pub. Date: Nov. 29, 2007

(54) Palladium-Plated Lead Finishing Structure For Semiconductor Part And Method Of Producing Semiconductor Device

(75) Inventors: Kazumitsu Seki, Nagano (JP); Takashi Yoshie, Nagano (JP); Muneaki Kure, Nagano (JP)

Correspondence Address: CHADBOURNE & PARKE LLP, 30 ROCKEFELER PLAZA, NEW YORK, NY, 10112, US

(73) Assignee: Shinko Electric Industries Co., Ltd., Nagano (JP)

(21) Appl. No.: 10/599,661

(22) PCT Filed: May 16, 2005
(86) PCT No.: PCT/JP05/09286

§ 371 Date: Oct. 4, 2006

(30) Foreign Application Priority Data
May 25, 2004 (JP) 2004-154656

(51) Int. Cl. H01L 23/495

(52) U.S. Cl. 174/536; 438/686; 257/E21.476

(57) ABSTRACT

A highly reliable plated lead finishing structure for a semiconductor part using a Pd film or a Pd alloy film, instead of a traditional solder plating material, as a brazing metal, without causing a problem of short-circuits between terminals due to whiskers, is provided. In the plated lead finishing structure of the invention, when a plated film having a thickness of not larger than 0.3 μm is formed using Pd or a Pd alloy (26), instead of a conventional solder-plating material as a brazing metal, on the surfaces of the external connection terminals (10, 12) of a semiconductor part using copper or a copper alloy-based material, the film is plated without interposing any underlying layer or any intermediate metal layer between the material and the Pd— or Pd alloy-plated layer. In some cases, Au or an Au alloy (28) is further plated and has a thickness of not larger than 0.1 μm on the plated film.

### TECHNICAL FIELD

The present invention relates to a palladium-plated lead finishing structure, and a method of producing a semiconductor device, in which the surfaces of a material constituting the external connection terminals of a semiconductor part, such as a lead frame, or a semiconductor package are plated with palladium or a palladium alloy.

### BACKGROUND ART

In mounting semiconductor parts, such as integrated circuit (IC) packages, on substrates by soldering, brazing or the like, it is becoming a generally accepted practice to join them in a state where no lead is contained from the standpoint of protecting the environment. Therefore, the terminal portions of the IC packages have been plated with a lead finishing solder of Sn/Ag (tin/silver), Sn/Bi (tin/bismuth) or Sn/Cu (tin/copper) instead of Sn/Pb (tin/lead) solder.

When it is attempted to carry out joining by a solder plating not containing lead, however, serious problems often arise in that burrs due to nodules (formation of masses) or abnormal deposition turn into plating slag at the time of forming the external terminals, to thereby cause short-circuits between the terminals, or, after mounting, whiskers that stem from the solder-plated portions cause short-circuits between the terminals. Besides, it is very difficult to control a solder-plating bath that does not contain a lead component and it has been not possible, to date, to stably deposit the plating film.

There has been known a lead frame called a Pd-PPF (Pd pre-plated lead frame) plated with palladium (Pd) or a Pd alloy film, in advance, as the lead finishing solder plating not containing lead (see JP 4-115558 A). In the conventional Pd-PPF, however, nickel (Ni) had to be used as an underlying metal so that the copper substrate of the lead frame can withstand the thermal history in the steps of assembling the IC package or the like and, particularly, in the step of mounting the semiconductor element by reflow. That is, copper or the copper alloy forming the lead frame substrate had to be prevented from diffusing into a palladium (Pd) film, a palladium alloy film or into a layer on the upper side thereof if a thermal history of a relatively high temperature acts thereon as in a reflow step.

When lead is not used in the lead finishing plating structure of the conventional semiconductor package, from the standpoint of protecting the environment as described above, there arises a problem of short-circuits between terminals caused by the formation of whiskers. Further, when a palladium (Pd) film or a Pd alloy film is to be plated on a substrate made of copper or a copper alloy, a nickel layer must be formed as an underlying layer of the Pd or Pd alloy film to prevent the diffusion of copper into the Pd layer or into the layer thereon (see JP 4-115558 A).

### DISCLOSURE OF THE INVENTION

It is therefore an object of the present invention to provide a plated lead finishing structure for semiconductor parts, which is capable of providing a highly reliable semiconductor package, by using a Pd film or a Pd alloy film instead of using the traditional solder plating material that works as a brazing metal, without causing problems, such as short-circuits between terminals caused by whiskers or the like, as in the conventional Pd-PPF (Pd pre-plated lead frame) as presented by a lead frame plated with three plating layers of Ni, Pd and Au, and which is, further, capable of stabilizing the step of lead finishing after the semiconductor package has been assembled.

In order to achieve the above object, according to the present invention, there is provided a palladium-plated lead finishing structure characterized in that Pd or a Pd alloy is plated to a thickness of not more than 0.3 μm on the surfaces of the external connection terminals of a semiconductor package using copper or a copper alloy-based material, without interposing any underlying layer or any intermediate metal layer between the material and the Pd— or Pd alloy-plated layer.

In this case, the invention is characterized in that Au or an Au alloy is plated to a thickness of not more than 0.1 μm on the upper surface of the Pd or Pd alloy layer to improve the wettability relative to the solder on the substrate on which the package is to be mounted.

According to the present invention, there is also provided a palladium-plated lead finishing structure characterized in that Pd or a Pd alloy is plated to a thickness of not more than 0.3 μm on the surfaces of the external connection terminals of a semiconductor package using iron or an iron-nickel-based material, without interposing any underlying layer or any intermediate metal layer between the material and the Pd— or Pd alloy-plated layer.

Further, the palladium-plated lead finishing structure of the present invention is characterized in that Au or an Au alloy is plated to a thickness of not more than 0.1 μm on the upper surface of the Pd or Pd alloy layer to improve the wettability relative to the solder on the substrate on which the package is to be mounted.

According to the present invention, there is also provided a method of producing a semiconductor package characterized by plating Pd or a Pd alloy to a thickness of not more than 0.3 μm on the surfaces of the external connection terminals of a semiconductor package using copper or a copper alloy-based material, without interposing any underlying layer or any intermediate metal layer between the surfaces of the material of the external connection terminals and the Pd— or Pd alloy-plated layer after at least the steps of mounting a semiconductor chip by die attachment, wire bonding and resin molding.

Further, according to the present invention, there is provided a method of producing a semiconductor package characterized by plating Pd or a Pd alloy to a thickness of not more than 0.3 μm on the surfaces of the external connection terminals of a semiconductor package using iron or an iron-nickel-based material, without interposing any underlying layer or any intermediate metal layer between the surfaces of the material of the external connection terminals and the Pd— or Pd alloy-plated layer after at least the steps of mounting a semiconductor chip by die attachment, wire bonding and resin molding.

Embodiments of the invention will now be described in detail with reference to the accompanying drawings.

### BRIEF DESCRIPTION OF THE DRAWINGS

FIG. 1 is a plan view of a semiconductor part, particularly, a lead frame, for which a palladium-plated lead finishing structure of the present invention can be employed;

FIGS. 2a and 2b are sectional views illustrating two examples of conventional palladium-plated lead finishing structures;

FIG. 3 is a sectional view of the palladium-plated lead finishing structure according to a first embodiment of the present invention;

FIG. 4 is a sectional view of the palladium-plated lead finishing structure according to a second embodiment of the present invention; and

FIG. 5 is a view of the appearance of a semiconductor device employing the palladium-plated lead finishing structure of the present invention.

### BEST MODE FOR CARRYING OUT THE INVENTION

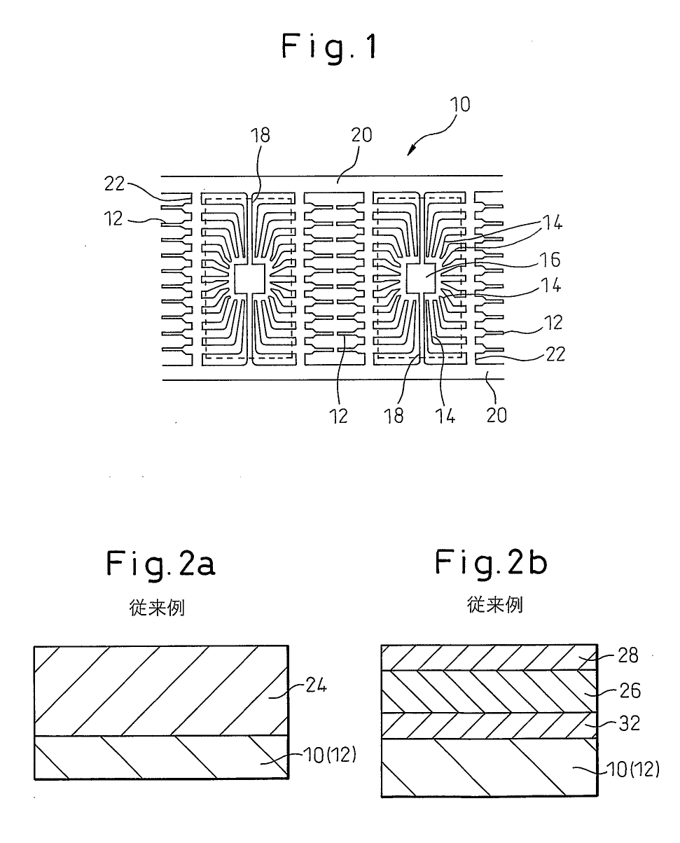

FIG. 1 is a plan view of a lead frame on which a palladium-plated lead finishing structure of a semiconductor package of the present invention can be employed.

In a lead frame 10 shown in FIG. 1, reference numeral 12 denotes outer leads, 14 denotes inner leads, and 16 denotes a chip-mounting portion on which a semiconductor chip (not shown) will be mounted and which is connected to rails 20 and 20 through support bars 18. Reference numeral 22 denotes a dambar.

On the lead frame 10, a semiconductor chip is mounted at the chip-mounting portion 16. The semiconductor chip is connected to the inner leads 14 through wires. The semiconductor chip, wires and inner leads 14 are molded with a resin to complete a semiconductor device. A solder film was formed in advance on the outer leads 12 of the semiconductor device, or the solder film is formed thereon at the time of mounting the semiconductor device on a substrate. Thus, the device is soldered onto a predetermined position of the substrate.

In the embodiment of the invention, a Pd film or a Pd alloy film is formed on the outer leads 12 after having been molded with a resin, without interposing an underlying layer or an intermediate layer such as Ni layer. In some cases, a thin Au film is further plated thereon.

There is no particular limitation on the material of the lead frame, and there can be used any material that is usually used, such as Cu, a Cu alloy or an Fe—Ni alloy.

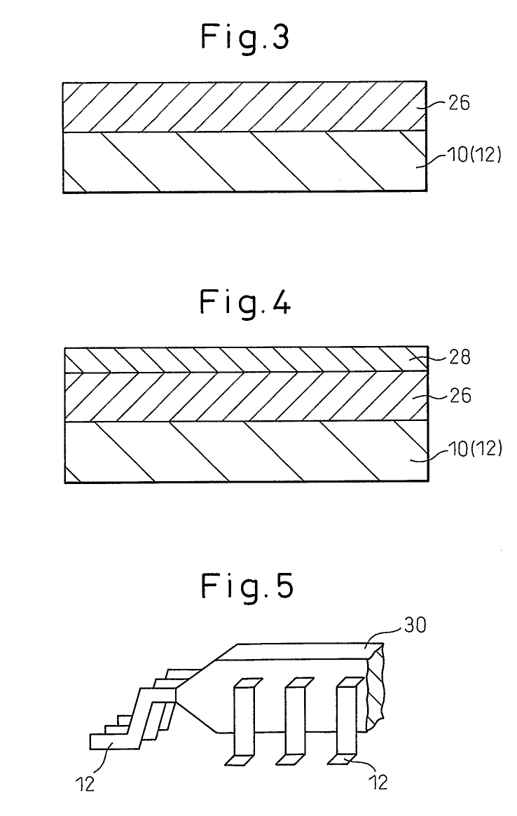

FIGS. 2a and 2b are sectional views schematically illustrating conventional solder-plated lead finishing structures of semiconductor packages or lead frames, FIG. 3 is a schematic sectional view of a first embodiment of the solder-plated lead finishing structure of a semiconductor package of the present invention, FIG. 4 is a schematic sectional view of a second embodiment, and FIG. 5 is a view of the appearance of the semiconductor device molded with a resin.

In the prior art of FIG. 2a, a solder-plated layer 24 with a thickness of about 10 μm is formed on a Cu substrate or on an Fe—Ni-based alloy substrate 10 forming the terminals of a lead frame. In the present invention as described above and as shown in FIG. 3, however, a Pd layer or a Pd alloy layer is plated directly on the Cu-based substrate or the Fe—Ni alloy-based substrate without using lead. Also, according to the present invention, a Pd layer or a Pd alloy layer 26 is directly formed on the lead frame substrate (outer lead) 10(12) without an interposed Ni layer, unlike the structure disclosed in JP 4-115558 A that is shown in FIG. 2b according to which a Pd-plated layer 26 is formed on the lead frame substrate (outer lead) 10(12), with an Ni layer 32 being interposed therebetween, and an Au layer 28 is further formed thereon.

That is, in the first embodiment of the present invention shown in FIG. 3, a palladium (Pd) layer or a Pd alloy layer 26 is plated to a thickness of not larger than 0.3 μm on a Cu substrate or the Fe—Ni-based alloy substrate 10(12) that forms the outer lead terminals of the lead frame for a semiconductor device. The Pd— or Pd alloy-plated layer 26 plays its role if it has a thickness of about 0.05 μm, in practice.

Further, in a second embodiment of the invention shown in FIG. 4, a palladium (Pd) layer or a Pd alloy layer 26 is plated to a thickness of not larger than 0.3 μm on a Cu substrate or the Fe—Ni-based alloy substrate 10(12) that forms the outer lead terminals of the lead frame for a semiconductor device like in the first embodiment and, on the top thereof, an Au layer 28 is further plated to a thickness of not larger than 0.1 μm. In practice, the Au-plated layer 28 has a thickness of 0.001 μm to 0.1 μm and, in the thinnest case, has a thickness that corresponds to a single Au atom. In the second embodiment as well, it is sufficient for the Pd— or Pd alloy-plated layer 26 to have a thickness of about 0.05 μm.

The conventional three-layer Pd-PPF (Pd pre-plated lead frame) structure in a lead frame or the like using the Pd film or the Pd alloy film instead of using the solder plating comprises, as shown in FIG. 2b, on a copper (Cu) substrate 10(12), an underlying metallic nickel (Ni) layer 32, an intermediate palladium (Pd) layer 26 and an uppermost gold (Au) layer 28. Such a three-layer Pd-PPF has an advantage in that it provides the lead frame with plating which allows the external terminals to be joined with the substrate by reflowing, before entering into the steps of assembling the semiconductor package, and makes it possible to omit a plating process after the assembling.

However, the steps of assembling such as of the die-attaching step for mounting of the semiconductor chip, the step of wire bonding and the step of molding with a resin involve cycle of thermal history. In order to prevent the lead frame from being oxidized by the thermal history and to ensure good solder-wetting properties after assembly, a Ni layer is provided as a layer for preventing the diffusion of Cu, a Pd layer is provided as a layer for preventing the diffusion of Ni, and an Au layer is provided as a layer for preventing the diffusion of Pd.

In the present invention, after the steps of assembling the semiconductor package, Pd 26 is plated on the terminals 10(12) of the package as shown in FIG. 3, or Pd 26 is plated on the terminals 10(12) of the package and Au 28 is further plated thereon as shown in FIG. 4, thereby eliminating the need of worrying about the oxidation of the lead frame caused by the thermal history in the steps of assembling such as of the die-attaching step for mounting the semiconductor chip, the step of wire bonding and the step of molding with a resin. Otherwise, even if steps of assembly such as the die-attaching, wire bonding and resin molding, are used, the temperature conditions of these steps can be suppressed to be so low that does not require any consideration regarding the oxidation of the lead frame.

According to the present invention, therefore, Ni as the underlying metal can be omitted and, in some cases, Au of the uppermost layer can be also omitted.

Affinity is poor between a noble metal, such as Pd or a Pd alloy of the plated layer 26, and the molding resin 30 (FIG. 5). Accordingly, the Ag-plated lead frame of the prior art tends to exhibit excellent adhesion to the molding resin compared with the Pd-PPF. Use of a lead-free solder that is now becoming normal, however, permits peeling to easily take place between the lead frame and the molding resin due to the reflow at a high temperature. Therefore, the conventional Ag-plated lead frame which is advantageous concerning the adhesion to the molding resin 30, may be commercially accepted.

In the case of the lead-free lead finishing solder plating, however, it is difficult to control the plating bath, and a stable film cannot be plated. There further exist problems of abnormal deposition and the occurrence of whiskers. Therefore, the lead finishing Pd solder plating may become effective even for conventional Ag-plated lead frames.

The Pd-PPF is not only used to join the external connection terminals to a substrate but also provides a plated film for wire bonding. At present, therefore, Ni, Pd and Au have been plated on the entire surface of the lead frame.

According to the present invention, however, the conventional Ag-plated lead frame is molded with a resin, i.e., molded with a resin 30 as shown in FIG. 5 and, thereafter, only the connection terminals of the outer leads 12 are plated with Pd 26, or are plated with Pd and subsequently with Au 28, thereby making it possible to greatly decrease the amounts of noble metals of Pd and Au used and to lower the price of the semiconductor packages.

Compared to the conventional lead-free lead finishing plated structure, therefore, the plated lead finishing structure for a semiconductor package of the present invention as described above offers the following advantages.
(1) Little probability of short-circuits, caused by whiskers resulting from solder plating, after the mounting. In contrast, in the case of the conventional lead-free lead finishing solder plating, great difficulty is involved in controlling the solder bath and in forming the stable plated film, giving rise to the occurrence of problems such as abnormal deposition and short-circuits between terminals due to whiskers or the like.
(2) In the case of the Pd plating, the plating bath is stable. Accordingly, the plating is easy to control, and the plated film is stable, leading to low probability of abnormal deposition, or short-circuits between the terminals due to whiskers.
(3) In the case of the solder plating, the thickness that is commonly required is about 10 μm and the plating deposition time is 60 to 120 seconds. In the case of the Pd plating, on the other hand, the thickness that is commonly required is about 0.05 μm and the plating deposition time is about 5 seconds, and even when Au is subsequently plated, the thickness thereof is very small and the plating deposition time is about 5 seconds, which enables the deposition time to be decreased to about one-tenth that of the prior art, leading to a great increase in productivity.

In the foregoing were described the embodiments of the invention with reference to the accompanying drawings. However, the invention is not limited to the above embodiments only, and various configurations, changes, modifications and the like may be possible within the spirit and scope of the invention.

### INDUSTRIAL APPLICABILITY

According to the present invention as described above, it is easy to control the plating bath, and the film that is formed is stable as compared with those of the lead-free lead finishing solder plating, and there is little probability of causing abnormal deposition and short-circuits, between terminals, caused by whiskers. Besides, the time needed for the plating can be shortened to greatly increase the productivity.

1. A palladium-plated lead finishing structure characterized in that Pd or a Pd alloy is plated to a thickness of not more than 0.3 μm on the surfaces of the external connection terminals of a semiconductor part using copper or a copper alloy-based material, without interposing any underlying layer or any intermediate metal layer between said material and said Pd— or Pd alloy-plated layer.

2. The palladium-plated lead finishing structure according to claim 1, wherein Au or an Au alloy is plated to a thickness of not more than b 0.1 μm on the top of said Pd or Pd alloy layer.

3. A palladium-plated lead finishing structure characterized in that Pd or a Pd alloy is plated to a thickness of not more than 0.3 μm on the surfaces of the external connection terminals of a semiconductor part using iron or an iron-nickel-based material, without interposing any underlying layer or any intermediate metal layer between said material and said Pd— or Pd alloy-plated layer.

4. The palladium-plated lead finishing structure according to claim 3, wherein Au or an Au alloy is plated to a thickness of not more than 0.1 μm on the top of said Pd or Pd alloy layer.

5. A method of producing a semiconductor device characterized by plating Pd or a Pd alloy, to a thickness of not larger than 0.3 μm, on the surfaces of the external connection terminals of a semiconductor part using copper or a copper alloy-based material, without interposing any underlying layer or any intermediate metal layer between the surfaces of said material of the external connection terminals and said Pd— or Pd alloy-plated layer after at least the steps of mounting a semiconductor chip by die attachment, wire bonding and resin molding.

6. A method of producing a semiconductor device characterized by plating Pd or a Pd alloy to a thickness of not more than 0.3 μm on the surfaces of the external connection terminals of a semiconductor part using iron or an iron-nickel-based material, without interposing any underlying layer or any intermediate metal layer between the surfaces of said material of the external connection terminals and said Pd— or Pd alloy-plated layer after at least the steps of mounting a semiconductor chip by die attachment, wire bonding and resin molding.
